(19) United States
(12) Patent Application Publication
(10) Pub. No.: US 2008/0220590 A1
(43) Pub. Date: Sep. 11, 2008

(54) Thin wafer dicing using UV laser

(75) Inventors: Mikel R. Miller, Dallas, TX (US); Vikas Gupta, Dallas, TX (US); Gregory Eric Howard, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/714,345

(22) Filed: Mar. 6, 2007

(51) Int. Cl. H01L 21/00; B23K 26/04

(52) U.S. Cl. 438/463; 219/121.67; 257/E21.001

(57) ABSTRACT

In a method and system for dicing a wafer (220), an ultraviolet (UV) laser (210) is aligned with a street (222) on the wafer (220). A thickness of the wafer (220) is at most 400 times a wavelength of the UV laser (210). When energized, the UV laser (210) generates an adjustable amount of energy in the form of a plurality of laser pulses (212) that are focused on the street (222). The amount of energy provided to the wafer (220) is adjustable in accordance to the thickness. The plurality of laser pulses (212) perform the dicing of the wafer (220) along the street (222) by ablating material from the wafer (220).

### BACKGROUND

This invention relates to fabrication of semiconductor devices and more particularly to use of tools and techniques for performing wafer processing operations such as wafer dicing.

FIG. 1 illustrates a view in perspective of a typical semiconductor wafer assembly 100, according to prior art. The wafer assembly 100 includes a wafer 110 containing a plurality of dies 120 arranged in a matrix fashion, a mounting tape 150 to adhesively mount the wafer 110, and a frame 160 to provide structural support to the assembly during the wafer processing. The plurality of dies 120, which are individual integrated circuits fabricated on a silicon substrate, are separated by a plurality of streets 130. An orientation marker 102 (e.g., in the form of a flat edge, a wafer flat, a wafer notch, or similar other) is placed on the wafer 110 to assist in the processing of the wafer 110. A physical cutting tool such as a saw blade (not shown) is typically used to dice, saw, or cut the wafer 110 along the desired plurality of streets 130 to generate partial wafers including producing singulated dies. A street width 132 is typically dependent on a thickness of the saw blade (also referred to as a kerf width) but is smaller than the dimensions of the singulated die. However, with decreasing size of the singulated die such as ones used in a radio frequency ID (RFID) chip, the street width 132 has a growing impact on the manufacturing cost.

Use of a physical saw blade causes die edge damage including crack formation, especially to devices with fragile low-k dielectrics or to thin wafers having a thickness not greater than about 100 microns. Such cracks may propagate into an active die area and may cause immediate or latent electrical failure of the semiconductor device. Use of a physical saw blade also requires a wider street width and increases the need to prepare a scribe seal around the singulated die to arrest development of the edge cracks due to the sawing process. Each of these limitations consumes valuable wafer real estate and thus reduces the yield measured by criteria such as number of die-per-wafer (DPW).

Use of an infra red (IR) laser to mill a trench before using a physical saw blade may mitigate some of the edge damage caused by the physical sawing process. However, the IR laser rapidly heats and melts the silicon back-end layers to form the trench, creating a thermal shock event which may cause localized, collateral damage. In addition, two trenches must be made, one on each side of the street, before physical sawing can occur. This activity consumes extra production time.

Therefore, traditional tools and methods for wafer dicing may be inadequate to reduce edge damage and improve yield, especially for dicing thin wafers. Also, use of multiple tools for wafer dicing reduces efficiency of manufacturing production.

### SUMMARY

Applicants recognize an existing need for an improved method and system for wafer dicing; and the need for an improved technique to reduce street width and minimize edge damage to dice thin wafers, absent the disadvantages found in the prior techniques discussed above.

The foregoing need is addressed by the teachings of the present disclosure, which relates to a system and method for dicing a wafer. According to one embodiment, in a method and system for dicing a wafer, an ultraviolet (UV) laser is aligned with a street on the wafer. A thickness of the wafer is at most 400 times a wavelength of the UV laser. When energized, the UV laser generates an adjustable amount of energy in the form of a plurality of laser pulses that are focused on the street. The amount of energy provided to the wafer is adjustable in accordance to the thickness. The plurality of laser pulses perform the dicing of the wafer along the street by ablating material from the wafer.

In one aspect of the disclosure, a system for wafer dicing includes an ultraviolet (UV) laser to generate a plurality of laser pulses. A thin wafer having a thickness of at most 400 times a wavelength of the plurality of laser pulses and capable of being diced along a street is aligned by a positioner to focus the plurality of laser pulses along the street. A controller coupled to the UV laser adjusts the plurality of laser pulses in accordance to the thickness. The plurality of pulses are focused to ablate material from the wafer along the street, thereby dicing the wafer.

Several advantages are achieved by the method and system according to the illustrative embodiments presented herein. The embodiments advantageously provide tools and techniques to dice wafers that are independent of making a physical contact between a dicing tool and the wafer. The wafer dicing is performed by single dicing tool that is independent of physical contact. The wafer dicing system incorporates a ‘cooler’ source of energy such as an ultraviolet (UV) laser, especially compared to a traditional infrared (IR) laser. The UV laser is cooler compared to the traditional IR laser since the rise in temperature of material near the vicinity of the UV laser beam is less compared to the rise in temperature of material near the vicinity of the IR laser. Additionally, a spot size of the UV laser beam is approximately 33% of the spot size of the IR laser beam. Thus, corresponding street width diced by the UV laser beam is narrower, thereby increasing the wafer yield. Material of the wafer is ablated by a breakup or dismantling of its lattice structure by the UV laser beam rather by a physical contact made by a saw blade. Edge damage and grit formation is therefore advantageously reduced. These improved tools and techniques are capable of dicing wafers in less time compared to traditional methods, and therefore improve manufacturing throughput and efficiency.

### BRIEF DESCRIPTION OF THE DRAWINGS

FIG. 1 illustrates a semiconductor wafer assembly, described herein above, according to prior art;

FIG. 2 illustrates a wafer dicing system, according to an embodiment;

FIG. 3A is a flow chart illustrating a method for dicing a wafer, according to an embodiment; and

FIG. 3B is a flow chart illustrating additional details of a method for adjusting energy of a UV laser, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements. Similarly, the functionality of various mechanical elements, members, and/or components for forming modules, sub-assemblies and assemblies assembled in accordance with a structure for an apparatus may be implemented using various materials and coupling techniques, depending on the application requirements. Descriptive and directional terms used in the written description such as top, bottom, left, right, and similar others, refer to the drawings themselves as laid out on the paper and not to physical limitations of the disclosure unless specifically noted. The accompanying drawings may not to be drawn to scale and some features of embodiments shown and described herein may be simplified or exaggerated for illustrating the principles, features, and advantages of the disclosure.

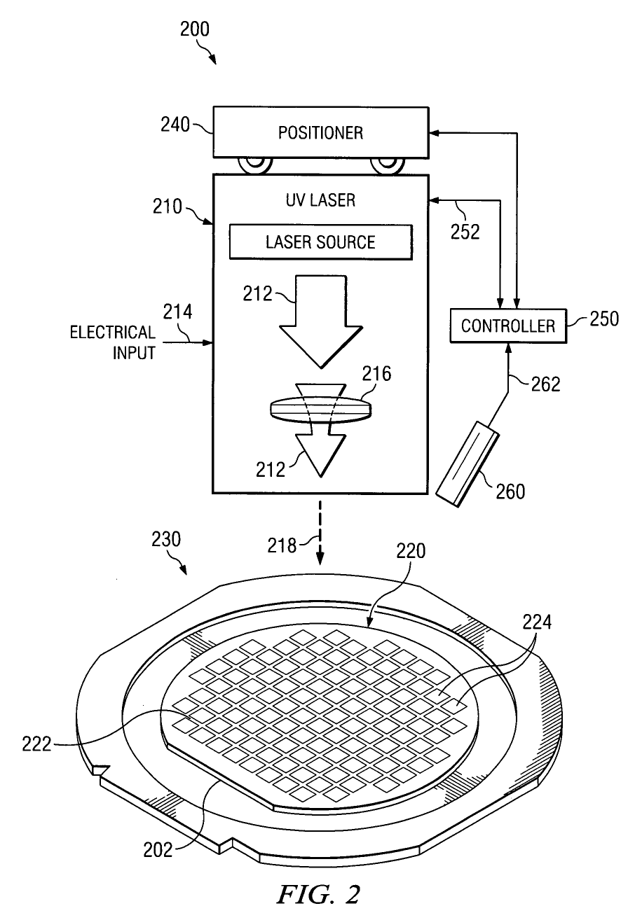

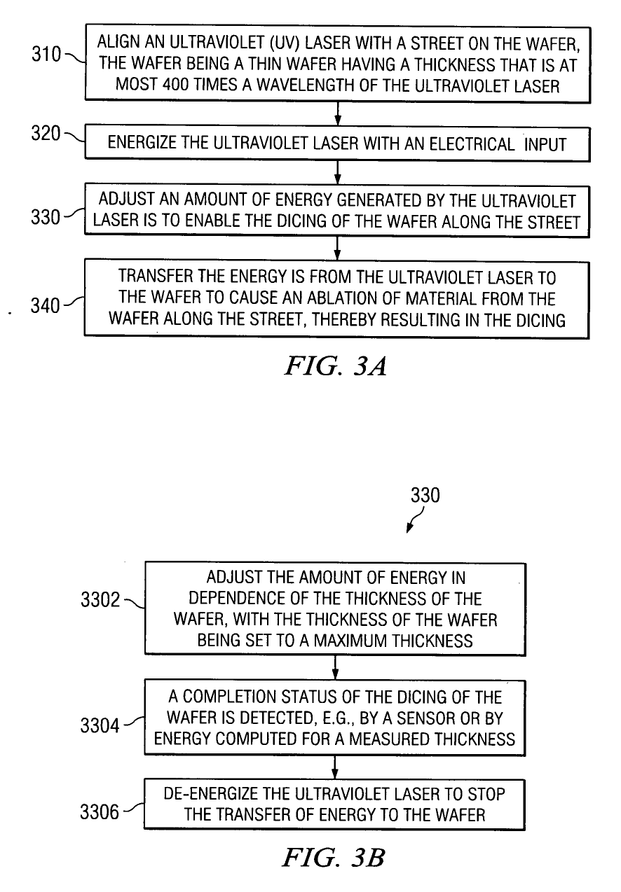

Traditional tools and methods for wafer dicing that are based on physical contact such as a saw blade or combination of IR laser and a saw blade may be inadequate to reduce edge damage and improve yield, especially for dicing thin wafers. This problem may be addressed by an improved system and method for wafer dicing. According to an embodiment, in an improved system and method for dicing a wafer, an ultraviolet (UV) laser is aligned with a street on the wafer. A thickness of the wafer is at most 400 times a wavelength of the UV laser. When energized, the UV laser generates an adjustable amount of energy in the form of a plurality of laser pulses that are focused on the street. The amount of energy provided to the wafer is adjustable in accordance to the thickness. The plurality of laser pulses perform the dicing of the wafer along the street by ablating material from the wafer. The systems and methods for dicing a wafer are described with reference to FIGS. 2, 3A and 3B.

The following terminology may be useful in understanding the present disclosure. It is to be understood that the terminology described herein is for the purpose of description and should not be regarded as limiting.

Wafer—A thin slice with parallel faces cut from a semiconductor material.

Ultraviolet (UV) laser—A laser is an acronym for light amplification by stimulated emission of radiation. It is a device that creates and amplifies a narrow, intense beam of coherent light. A UV laser is a laser device which operates in the ultraviolet range of the electromagnetic spectrum. The UV laser is a source of energy which is capable of breaking chemical bonds, dismantling material structures, and ionizing molecules. Typical wavelengths for the UV laser are 266 nanometers and 355 nanometers, although other wavelengths such as 337 nanometers and 400-480 nanometers (blue UV lasers) are also available. The energy may be generated in the form of a continuous beam or as a plurality of laser pulses.

FIG. 2 illustrates a wafer dicing system 200, according to an embodiment. The wafer dicing system 200 includes an UV laser 210 that is operable to generate energy in the form a switched or continuous wave signal. In the depicted embodiment, the UV laser 210 is powered by an electrical input 214 and generates the energy in the form a plurality of laser pulses 212. As described earlier, the UV laser 210 is a laser device which operates in the ultraviolet range of the electromagnetic spectrum. The UV laser 210 is a source of energy which is capable of breaking chemical bonds, dismantling material structures, and ionizing molecules. Typical wavelengths for the UV laser 210 are 266 nanometers and 355 nanometers, although other wavelengths such as 337 nanometers and 400-480 nanometers (blue UV lasers) are also available. The plurality of pulses 212 are generated by a UV laser source and collimated by a lens 216 into a laser beam 218, which (depending on the wavelength) may be visible as an intense beam of light.

The energy is directed to and transferred to a selectable spot on the wafer 220 to perform the dicing. In the depicted embodiment, the plurality of pulses 212 are aligned with the selectable spot on a street 222 of a wafer 220, the wafer 220 being part of a wafer assembly 230. A spot size for the plurality of laser pulses 212 having the wavelength of 355 nanometers is approximately 33% of a spot size for a plurality of laser pulses of an infra red (IR) laser having a wavelength of 1064 nanometers. Thus, a corresponding street width generated by the plurality of laser pulses 212 is at least approximately 33% less compared to traditional street widths. Smaller street widths advantageously improve the wafer yield. Additionally, the UV laser 210 is cooler compared to the traditional IR laser since the rise in temperature of wafer material near the vicinity of the UV laser beam 218 spot is less compared to the rise in temperature of wafer material near the vicinity of the IR laser beam spot. As described earlier, the IR laser rapidly heats and often melts the silicon back-end layers of a wafer.

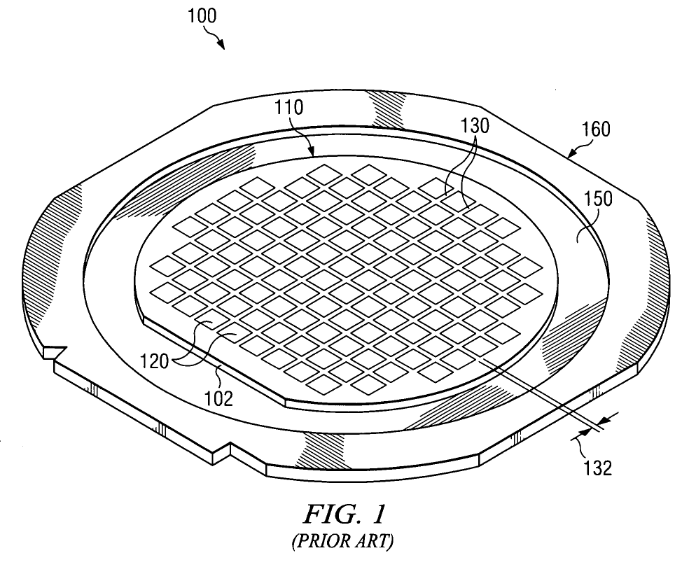

In the depicted embodiment, the wafer 220 is a thin wafer having a thickness between approximately 5 microns to approximately 100 microns. Thus, the maximum thickness is approximately at most 400 times a wavelength of the plurality of laser pulses 212. It is understood that the range of the thickness may vary with improvements in technology. In an embodiment, the wafer assembly 230 and the wafer 220 are substantially the same as the wafer assembly 100 and the wafer 110 described with reference to FIG. 1. The wafer 220 is capable of being diced along the street 222 by applying the focused laser beam 218.

A positioner 240 is operable to continually position at least one of the UV laser 210 and the wafer 220 to properly align the laser beam 218 at the selectable spot on the street 222. The positioner 240 may include servo motors (not shown) to provide multi dimensional motion control to achieve the desired alignment and the desired dicing length and direction. In an embodiment, the positioner 240 may be coupled to the UV laser 210 to position the laser beam 218. In an exemplary non-depicted embodiment, the positioner 240 may be removably coupled to the wafer assembly 230 for properly positioning the wafer assembly 230. The positioner 230 uses an orientation marker 202 on the wafer 220 to perform the alignment and location of the selectable target spot on the street 222.

The wafer dicing system 200 includes a controller 250 to control the wafer dicing. The controller 250 is operable to control an amount of the energy transferred to the wafer 220 by controlling an amplitude or pulse width (or both) of the plurality of pulses 212. The controller 250 may also provide motion control for the positioner 230. The amount of energy transferred to the wafer 220 is controllable in accordance with the thickness of the wafer 220. That is, the controller 250 adjusts a particular pulse width (or pulse duration) of the plurality of pulses 212 and a time interval for the transfer, thereby controlling the amount of energy transferred, to dice through a measured thickness of the wafer 220. Other characteristics of the wafer dicing system 200 which may be controlled by the controller 250 may include average and peak power output, pulse repetition rates, and dicing speed. Average power output for the UV laser 210 may vary from 1 milliwatt to about 5 watts, average pulse repetition rates may be adjusted up to 100 kilohertz, and dicing speeds up to 1000 millimeters per second may be supported. It is understood that actual dicing speed may vary depending on factors such as scribe width, wafer thickness, and wafer material.

In an embodiment, an optional sensor 260 is coupled to the controller 250 and may be used to detect a presence of the plurality of pulses 212. The sensor 260 may be a charge coupled device (CCD) camera to detect a reflected wave of the plurality of pulses 212. In this embodiment, the controller 250 is operable to set the UV laser 210 to the maximum energy output level, e.g., by adjusting the pulse width to a maximum level corresponding to the maximum thickness of the wafer 220. An absence of a reflected signal of the plurality of pulses 212 may indicate a completion of the wafer dicing. The controller 250 provides a control signal 252 to the UV laser 210 to be de-energized and stop the plurality of laser pulses 212 in response to an input 262 from the sensor 260 indicating an absence of the reflected signal of the plurality of laser pulses. In an exemplary, non-depicted embodiment, a UV laser detection sensor may be disposed below the wafer 220 to detect the dicing status.

Dicing of the wafer 220 occurs through ablation of wafer material. The plurality of pulses 212 are focused to ablate material from the wafer 220 along the street 222. A bandgap for semiconductor material of the wafer 220 is about 1.1 electron volts. The plurality of pulses 212 having an energy level of approximately 3 electron volts is able to breakup the lattice structure of the semiconductor material at the focused spot. The breakup of the material results in the dicing of the wafer 220. Thus, transfer of the energy from the UV laser 210 to the wafer 220 advantageously occurs without a physical contact there between, thereby providing wafer dicing without causing substantial wafer damage such as edge cracks.

In an embodiment, the wafer 220 includes a plurality of dies 224, which may be singulated by the wafer dicing system 200. In a particular embodiment, the singulated die is one of a microprocessor, a digital signal processor, a radio frequency chip, a memory, a microcontroller, and a system-on-a-chip, or a combination thereof. In an embodiment, dimensions of the sigulated die are at least 500 microns by 500 microns.

FIGS. 3A and 3B are flow charts illustrating a method for dicing a wafer, according to an embodiment. In a particular embodiment, the method may be used to dice the wafer 220 described with reference to FIG. 2. Referring to FIG. 3A, at step 310, an ultraviolet (UV) laser is aligned with a street on the wafer. The wafer is a thin wafer having a thickness that is at most 400 times a wavelength of the UV laser. At step 320, the UV laser is energized with an electrical input. At step 330, an amount of energy generated by the UV laser is adjusted to enable the dicing of the wafer along the street. At step 340, the energy is transferred from the UV laser to the wafer to cause an ablation of material from the wafer along the street, thereby resulting in the dicing.

Various steps described above may be added, omitted, combined, altered, or performed in different orders. For example, the step 330 may include executing steps 3302, 3304, and 3306 described with reference to FIG. 3B.

FIG. 3B is a flow chart illustrating additional details of a method for adjusting energy of a UV laser, according to an embodiment. At step 3302, the amount of energy is adjusted in accordance to the thickness of the wafer, with the thickness of the wafer being set to a maximum thickness. At step 3304, a completion status of the dicing of the wafer is detected, e.g., by a sensor or by energy computation for a measured thickness. At step 3306, the UV laser is de-energized to stop the transfer of the energy to the wafer. Various steps described above may be added, omitted, combined, altered, or performed in different orders.

Several advantages are achieved by the method and system according to the illustrative embodiments presented herein. The embodiments advantageously provide tools and techniques to dice wafers that are independent of making a physical contact between a dicing tool and the wafer. The wafer dicing is performed by a ‘cooler’ source of energy such as an ultraviolet (UV) laser. The UV laser is cooler compared to a traditional infrared (IR) laser since the rise in temperature of material near the vicinity of the UV laser beam is less compared to the rise in temperature of material near the vicinity of the IR laser. Additionally, a spot size of the UV laser beam is approximately 33% of the spot size of the IR laser beam. Thus, corresponding street width diced by the UV laser beam is narrower, thereby increasing the wafer yield. Material of the wafer is ablated by breakup or dismantling of its lattice structure by the UV laser beam rather by a physical contact made by a saw blade. Edge damage is therefore advantageously reduced. These improved tools and techniques are capable of dicing wafers in less time compared to traditional methods, and therefore improve manufacturing throughput and efficiency.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, although not illustrated, alternative forms, shapes, and materials of semiconductor wafers containing a plurality of dies may be possible. Some wafers may have a circular shape with a notch as a reference for orientation but without the wafer flat. As another example, although a UV laser is described as a source of energy, those of ordinary skill in the art will appreciate that the processes disclosed herein are capable of being used for wafer dicing having other types of energy sources that are capable of delivering sufficient energy to breakup the lattice structure of the wafer material.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for dicing a wafer, the method comprising:
aligning an ultraviolet (UV) laser with a street on the wafer, a thickness of the wafer being at most 400 times a wavelength of the UV laser;
energizing the UV laser;
adjusting an amount of energy generated by the UV laser to enable the dicing; and
transferring the energy from the UV laser to the wafer, the transferring of the energy causing an ablation of material from the wafer along the street, thereby resulting in the dicing.

2. The method of claim 1 further comprising:
adjusting the amount of energy in accordance to the thickness, wherein the thickness is set to a maximum thickness;
detecting a completion of the dicing of the wafer; and
de-energizing the UV laser to stop the transfer of the energy.

3. The method of claim 2, wherein the completion of the dicing is detectable by a sensor operable to detect the UV laser.

4. The method of claim 1, wherein the adjusting of the amount of energy generated by the UV laser is made by adjusting a pulse duration of the UV laser.

5. The method of claim 1, wherein the adjusting of the amount of energy is in accordance to the thickness, wherein the thickness is a measured thickness of the wafer.

6. The method of claim 1, wherein the wavelength of the UV laser is approximately 355 nanometers.

7. The method of claim 6, wherein a spot size for the UV laser having the wavelength of 355 nanometers is approximately 33% of a spot size for an infra red (IR) laser having a wavelength of 1064 nanometers.

8. The method of claim 7, wherein the spot size for the UV laser is not greater than a width of the street.

9. The method of claim 1, wherein the amount of energy generated by the UV laser to enable the dicing is greater than a threshold value of approximately 1.1 electron volts, preferably approximately 3 electron volts.

10. The method of claim 1, wherein a die included on the wafer has dimensions of at least 500 microns by 500 microns.

11. The method of claim 10, wherein the die is one of a microprocessor, a digital signal processor, a radio frequency chip, a memory, a microcontroller, and a system-on-a-chip, or a combination thereof.

12. The method of claim 1, wherein the transferring of the energy from the UV laser to the wafer occurs without a physical contact therebetween.

13. A wafer dicing system, the system comprising:
an ultraviolet (UV) laser to generate a plurality of laser pulses;
a wafer having a thickness of at most 400 times a wavelength of the plurality of laser pulses, the wafer capable of being diced along a street;
a positioner to focus the plurality of laser pulses along the street; and
a controller to adjust the plurality of laser pulses in accordance to the thickness, the plurality of pulses being focused to ablate material from the wafer along the street.

14. The system of claim 13 further comprising:
a sensor coupled to the controller, the sensor being operable to detect a presence of the plurality of laser pulses, the controller providing a control signal to the UV laser to stop the plurality of laser pulses in response to an input from the sensor indicating an absence of the plurality of laser pulses.

15. The system of claim 13, wherein the plurality of pulses ablate material from the wafer without a physical contact between the UV laser and the wafer.

16. The system of claim 13, wherein the wavelength of the plurality of laser pulses is approximately 355 nanometers.

17. The system of claim 16, wherein a spot size for the plurality of laser pulses having the wavelength of 355 nanometers is approximately 33% of a spot size for a plurality of laser pulses of an infra red (IR) laser having a wavelength of 1064 nanometers.

18. The system of claim 13, wherein the controller adjusts the plurality of laser pulses to deliver an amount of energy to the wafer, the amount of energy being greater than a threshold value of approximately 1.1 electron volts, preferably approximately 3 electron volts.

19. The system of claim 13, wherein the controller adjusts the plurality of laser pulses in accordance to the thickness by adjusting a pulse width of the plurality of laser pulses.

20. The system of claim 13, wherein the wafer contains a plurality of integrated circuit dies, wherein one of the integrated circuit dies is one of a microprocessor, a digital signal processor, a radio frequency chip, a memory, a microcontroller, and a system-on-a-chip, or a combination thereof.
